(19) United States
(12) Patent Application Publication
(10) Pub. No.: US 2014/0238471 A1
(43) Pub. Date: Aug. 28, 2014

(54) Multi-Component Type Curable Silicone Rubber Composition, Material For Electronic Parts Using Such, And Solar Cell Module

(71) Applicant: Dow Corning Toray Co., Ltd., Tokyo (JP)

(72) Inventors: Keiji Wakita, Ichihara-shi (JP); Osamu Takuman, Ichihara-shi (JP); Manabu Sutoh, Ichihara-shi (JP)

(21) Appl. No.: 14/348,089

(22) PCT Filed: Dec. 26, 2012
(86) PCT No.: PCT/JP2012/084276

§ 371 Date: Mar. 28, 2014

(30) Foreign Application Priority Data
Dec. 29, 2011 (JP) 2011-290322

(51) Int. Cl. C08L 83/04; H01L 31/048

(52) U.S. Cl. CPC C08L 83/04; H01L 31/0481
USPC 136/251; 524/588; 524/500

(57) ABSTRACT

A multi-component type curable silicone rubber composition includes: (A) 100 parts by weight of an organopoly-siloxane capped at molecular terminals with an alkoxy group or silanol group, (B) 0.5 to 20.0 parts by weight of an organic compound having at least two alkoxysilyl groups within single molecule and including a non-silicon-oxygen bond between the silyl groups, (C) 0.05 to 2.0 parts by weight of water, and (D) a catalytic amount of a curing catalyst. The multi-component type curable silicone rubber composition is composed of multiple separately stored compositions.

### TECHNICAL FIELD

Priority is claimed on Japanese Patent Application No.2011-290322, filed on Dec. 29, 2011, the content of which is incorporated herein by reference.

The present invention relates to a multi-component type curable silicone rubber composition characterized as having excellent deep part curability, adhesivity, and reversion resistance, and characterized as being composed of multiple separately-stored compositions. Moreover, the present invention relates to a material used for electronic parts utilizing this same composition, and particularly to a potting material for solar cell parts. The present invention further relates to a solar cell module using this same composition and to a method for manufacture of a terminal box used for solar cells.

### BACKGROUND ART

It is known that some specific multi-component room-temperature-curable silicone rubber compositions in the form of two-package-type liquid compositions or the like, the properties of which are not affected by atmospheric moisture, are widely used as sealing materials that possess excellent deep curability and allow substantially uniform curing throughout the entire body of the sealing material, i.e., from the surface to the inner part. For example, Japanese Unexamined Patent Application Publication (hereinafter referred to as “Kokai”) S48-37452A describes a two-package-type liquid room-temperature-curable silicone rubber composition comprising the following: a base composition composed of a filler and a diorganopolysiloxane capped at molecular terminals with silanol groups; and a catalyst composition consisting of an alkyl silicate, an amino-functional silane, and a curing catalyst.

On the other hand, solar cells are rapidly being developed in recent years as a representative source of renewable energy. Reduction of manufacturing cost is a prime task for solar cells to become truly effective as an energy source. Multi-component type silicone rubber compositions, which have excellent curability, are of increased importance as materials capable of reducing the time needed for overall curing and capable of reducing labor time. That is to say, the above mentioned deep part curability is important.

Moreover, looking at the overall system cost of a solar cell electrical generation system, system working life affects the direct electricity generation cost price. Long-term durability of materials is thus very important. Silicone rubber compositions are useful also from the standpoint of long-term durability.

However, as mentioned, for example, in Japanese Unexamined Patent Application Publication H11-340652A (Patent Document 2), such a multi-component type silicone rubber composition has a problem in that a composition that was cured under conditions where part of the composition was insufficiently cured may markedly soften or liquefy (i.e. problem referred to below as “reversion”). In particular, durability testing for solar cell applications is generally performed by aging testing under high temperature and high humidity conditions. Existing multi-component silicone rubber compositions have not necessarily been sufficient from the standpoint of stability under such conditions.

Technology is known that blends in a disilaalkane as a means for solving this type of problem. For example, Japanese Unexamined Patent Application Publication 2009-132797A (Patent Document 3) discloses technology using a disilaalkane containing composition as a potting material, and WO2008/152042 (Patent Document 4) discloses the ability to use a sealant composition containing a disilaalkane as a sealant for solar cells. However, both of these compositions have had difficulty in simultaneously obtaining deep part curability as well as adhesivity and durability.

Furthermore, Japanese Unexamined Patent Application Publication No. H07-003159A (Patent Document 5) or the like discloses improvement of deep part curability by addition of water to a silicone rubber composition. However, there is neither mention nor suggestion of the specific utilized amount of water or a system jointly using water addition and a disilaalkane. Moreover, there has been no specific disclosure concerning the effect and specific applications of such.

### PRIOR ART DOCUMENTS

### Patent Documents

Patent Document 1: Japanese Unexamined Patent Application Publication No. S-48-37452A
Patent Document 2: Japanese Unexamined Patent Application Publication No. H11-340652A
Patent Document 3: Japanese Unexamined Patent Application Publication No. 2009-132797A
Patent Document 4: WO2008/152042
Patent Document 5: Japanese Unexamined Patent Application Publication No. H07-003159A

### SUMMARY OF INVENTION

### Technical Problem

The object of the present invention is to provide a multi-component type curable silicone rubber composition having excellent deep part curability, adhesivity, and reversion resistance, as well as rapid curability (i.e. a characteristic of a multi-component type composition) so that use is possible with advantage as a material for electronic parts (i.e. solar cells or the like), and particularly as a potting material for solar cell parts. Furthermore, an object of the present invention is to solve problems of deep part curability, adhesivity, and reversion, and to provide a solar cell module having excellent long-term durability and reliability. In particular, an object of the present invention is to provide a method for manufacture of a terminal box for solar cells that is capable of manufacturing with good workability and reliability a terminal box for solar cells requiring excellent long-term durability and reliability.

### Solution to Problem

As a result of dedicated investigations, the inventors of the present invention accomplished the present invention by discovery of the ability to solve the aforementioned problems by joint use of water and a fixed amount of an organic compound having an alkoxysilyl group (i.e. disilaalkane or the like) in a multi-component type curable silicone rubber composition, particularly when the composition is used for a multi-component type silicone rubber used in solar cell applications.

More specifically, the present inventors achieved the present invention by discovery of the ability to solve the aforementioned problems by a multi-component type curable silicone rubber composition including:
(A) 100 parts by weight of an organopolysiloxane capped at molecular terminals with an alkoxy group or silanol group;
(B) 0.5 to 20.0 parts by weight of an organic compound having at least two alkoxysilyl groups within single molecule and including a non-silicon-oxygen bond between the silyl groups;
(C) 0.5 to 2.0 parts by weight of water; and
(D) a catalytic amount of a condensation curing catalyst;
   where the multi-component type curable silicone rubber composition is composed of multiple separately stored compositions.

Moreover, the inventors of the present invention achieved the present invention by discovery of the ability to better solve the aforementioned problems when the aforementioned component (B) is a disilaalkane compound indicated by General Formula.

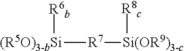

Within this formula, R⁵ and R⁹ are each an alkyl group or an alkoxyalkyl group; R⁶ and R⁸ are each a monovalent hydrocarbon group; R⁷ is an optionally substituted alkylene group having 2 to 20 carbon atoms; and b and c are each 0 or 1.

Moreover, the inventors of the present invention achieved the present invention by discovery of the ability to solve the aforementioned problem by a solar cell module characterized in that, during manufacture of the solar cell module, at least part of the components composing the module (i.e. at least one component from among the seal material for sealing a terminal, adhesive material (for the protective frame, reinforcing member, installation member, or the like), terminal box adhesive, and sealing material for the terminal box interior) is a cured material composed of the aforementioned multi-component type curable silicone rubber composition.

That is, the aforementioned object is achieved by
“[1] A multi-component type curable silicone rubber composition including:
(A) 100 parts by weight of an organopolysiloxane capped at molecular terminals with an alkoxy group or silanol group;
(B) 0.5 to 20.0 parts by weight of an organic compound having at least two alkoxysilyl groups within single molecule and including a non-silicon-oxygen bond between the silyl groups;
(C) 0.5 to 2.0 parts by weight of water; and
(D) a catalytic amount of a condensation curing catalyst;
   where the multi-component type curable silicone rubber composition includes multiple separately stored compositions.
[2] The multi-component type curable silicone rubber composition according to [1];
   where the aforementioned component (B) is a disilaalkane compound indicated by General Formula.

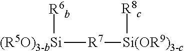

Within the formula, R⁵ and R⁹ are each an alkyl group or an alkoxyalkyl group; R⁶ and R⁸ is a monovalent hydrocarbon group; R⁷ is an optionally substituted alkylene group having 2 to 20 carbon atoms; and b and c are each 0 or 1.
[3] The multi-component type curable silicone rubber composition according to [1] or [2]; where blended amount weight ratio of the aforementioned component (C) relative to the aforementioned component (B) is in a range of 0.05 to 1.0.
[4] The multi-component type curable silicone rubber composition according to any one of [1] to [3]; where the composition further includes (F) 0.1 to 20.0 parts by weight of an adhesion-giving component.
[5] The multi-component type curable silicone rubber composition according to any one of [1] to [4];
   where the multi-component type curable silicone rubber composition is a two-component type room temperature curable silicone rubber composition using:
(I) a composition including at least the aforementioned component (A) and component (C), and not including the aforementioned component (D); and
(II) a composition including at least the aforementioned component (D), and not including the aforementioned (A) component and component (C).
[6] The multi-component type curable silicone rubber composition according to any one of [1] to [5];
   where the multi-component type curable silicone rubber composition is a potting material used for electrical/electronic parts, a sealing agent used for electrical/electronic parts, or an adhesive material used for electrical/electronic parts.
[7] The multi-component type curable silicone rubber composition according to any one of [1] to [6]; where the multi-component type curable silicone rubber composition is a potting material used for a solar cell component.
[8] A solar cell module having a cured material including the multi-component type curable silicone rubber composition according to any one of [1] to [7] as at least part of an article forming the module.
[9] A solar cell module having as at least part of a terminal box a cured material that is the multi-component type curable silicone rubber composition according to any one of [1] to [7].
[10] A production method of a terminal box used for a solar cell; where the method includes a step of using the multi-component type curable silicone rubber composition according to any one of [1] to [7].”

### Advantageous Effects of Invention

The present invention has excellent deep part curability, adhesivity, and reversion resistance and is able to contribute to greater workability by rapid curing, which is a characteristic of a multi-component type curable silicone rubber composition. The present invention is thus able to provide a multi-component type curable silicone rubber composition that is capable of being used suitably as a material for electronic parts (such as solar cells and the like) and particularly as a potting material for solar cell parts.

Furthermore, the present invention is able to solve the problems of deep part curability, adhesivity, and reversion and to provide a solar cell module that has excellent long-term durability and reliability. In particular, the present invention is able to provide a terminal box for solar cells that is particularly vital for a solar cell module having excellent long-term durability and reliability. In particular, the present invention may provide a method for production of a terminal box for solar cells that is capable of being produced with good workability and reliability.

### DESCRIPTION OF THE INVENTION

The multi-component type curable silicone rubber composition of the present invention will be described in detail. The multi-component type curable silicone rubber composition of the present invention is characterized as being produced by blending of a multiplicity of separately stored compositions and including:
(A) 100 parts by weight of an organopolysiloxane capped at molecular terminals with an alkoxy group or silanol group;
(B) 0.5 to 20.0 parts by weight of an organic compound having at least two alkoxysilyl groups within single molecule and including a non-silicon-oxygen bond between the silyl groups;
(C) 0.5 to 2.0 parts by weight of water; and
(D) a catalytic amount of a condensation curing catalyst.

Moreover, at least part of a part constituting the solar cell module of the present invention (i.e. seal material for sealing the terminals of the module; adhesive material for the protective frame, reinforcing member, installation member, or the like; terminal box adhesive, or terminal box interior sealant) is the aforementioned multi-component type curable silicone rubber composition. In particular, the solar cell module of the present invention preferably has cured multi-component type curable silicone rubber composition of the present invention as at least part of the terminal box of the solar cell module.

The component (A) is an organopolysiloxane capped at molecular terminals with an alkoxy group or silanol group and is one of the main agents of the aforementioned multi-component type curable silicone rubber composition. The component (A) may be an (A-1) organopolysiloxane capped at the both molecular terminals with the alkoxy group or silanol group, or may be a mixture of the aforementioned component (A-1) and an (A-2) organopolysiloxane capped at molecular terminals with the alkoxy group or silanol group. However, the strength of the cured silicone rubber or adhesivity sometimes decreases when the amount of the single-terminus type component (A-2) is excessive. Thus the mixing ratio (weight ratio) is preferably in the range of (A-1): (A-2)=(100:0) to (20:80), and the range of (A-1): (A-2)=(100:0) to (30:70) is further preferred. Most preferably, the component (A) is composed only of a (A-1) organopolysiloxane capped at the both molecular terminals with a silanol group.

Although no particular limitation is placed on the viscosity of the component (A) at 25° C., strength of the cured silicone rubber declines if the viscosity is excessively low. When viscosity of the component (A) is excessively high, there is a tendency for manufacturing time and workability at the time of use to decline. Thus this viscosity is preferably in the range of 20 to 1,000,000 mPa·s, and particularly preferably is in the range of 100 to 100,000 mPa·s. This viscosity is most preferably in the range of 150 to 10,000 mPa·s.

The component (A) is capped at molecular terminals with alkoxy group or silanol group and forms a silicone rubber by curing by a condensation reaction in the presence of the below described (D) curing catalyst. In particular, the component (A) preferably is an organopolysiloxane having the chain terminated by a silanol group (—OH) or by a silyl group having a 1 to 10 carbon number alkoxy group.

Preferable component (A-1) is a diorganopolysiloxane expressed by the following general formula.

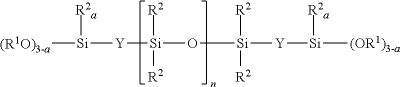

In this formula, R¹ represents a hydrogen atom or a group selected from a methyl, ethyl, propyl, butyl, octyl, or a similar alkyl group having from 1 to 10 carbons; and a methoxymethyl, methoxyethyl, ethoxymethyl, ethoxyethyl, or a similar alkoxyalkyl group. Among these, a hydrogen atom, a methyl group, and an ethyl group are preferable. R² represents a group selected from a monovalent hydrocarbon group, a halogenated hydrocarbon group, and a cyanoalkyl group. Specific examples of the R² moiety include a methyl, ethyl, propyl, butyl, octyl, or similar alkyl group having from 1 to 10 carbons; a cyclopentyl, cyclohexyl, or similar cycloalkyl group; a vinyl, allyl, or similar alkenyl group; a phenyl, tolyl, naphthyl, or similar aryl group; a benzyl, phenylethyl, phenylpropyl, or similar aralkyl group; a trifluoropropyl, chloropropyl, or similar halogenated hydrocarbon group; and a 2-cyanoethyl, 3-cyanopropyl, or a similar cyanoalkyl group. Of these, a methyl group or an ethyl group is preferable. When R¹ is an alkyl group or alkoxyalkyl group, “a” is 0, 1, or 2. The value of “a” is preferably 0 or 1 and more preferably is 1. “a” is 2 when R¹ is the hydrogen atom.

In the above formula, Y represents an oxygen atom, a divalent hydrocarbon group, or a group expressed by the following general formula.

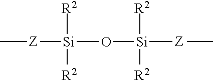

In this formula, the R² moiety is the same as defined above, and Z is a divalent hydrocarbon group. Y is particularly preferably the oxygen atom. The divalent hydrocarbon group (Z) is preferably a methylene, ethylene, propylene, butylene, hexene, or similar alkylene group having 1 or more carbons. Furthermore, n is a number such that viscosity at 25° C. for the component (A-1) is in the aforementioned range.

The component (A-1) can be manufactured via a known method such as, for example, that described in Japanese Examined Patent Application Publication No. H03-4566 or Kokai S63-270762.

In the composition of the present invention, component (A-2) functions to reduce the modulus of elasticity of a silicone rubber (cured product of the composition of the present invention), improve adhesion to hard-to-adhere substrates, or the like. The component (A-2) is preferably a diorganopolysiloxane expressed by the following general formula.

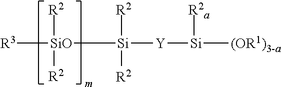

In this formula, the R¹, R², Y, and “a” moieties are the same as defined above. R³represents a methyl, ethyl, propyl, butyl, octyl, or similar alkyl group having from 1 to 10 carbons; or a vinyl, allyl, or similar alkenyl group. Among these, an alkyl group having from 1 to 10 carbons is preferable, and a methyl group is more preferable. Here, m is a number such that viscosity of the component (A-2) at 25° C. is within the aforementioned range.

The component (A-2) can be manufactured via a known method such as, for example, that described in Japanese Examined Patent Application Publication No. H04-13767 or Japanese Examined Patent Application Publication No. S63-270762.

The component (B) is an organic compound having at least two alkoxysilyl groups within a single molecule and including a non-silicon-oxygen bond between the silyl groups. This is one component characterized in that, by joint use with the below described component (C) according to the present invention, deep part curability, adhesivity, and reversion resistance are improved. Furthermore, sometimes the adhesion and water resistance of the two-component type room temperature curable silicone rubber composition of the present invention may be further improved by joint use of the component (B) with a reaction mixture of an amino group-containing alkoxysilane and an epoxy compound (such as disclosed in Japanese Unexamined Patent Application Publication No. 2003-221506).

The component (B) has at least two alkoxysilyl groups in the molecule and is an organic compound that includes a non-silicon-oxygen bond between these silyl groups. The component (B) is preferably a hydrocarbon having alkoxysilyl groups as indicated by the below listed general formula.

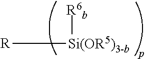

Within this formula, R⁵ is each independently alkyl group or alkoxyalkyl group; R⁶ is each independently monovalent hydrocarbon group; R is a p-valent hydrocarbon group; p is a number greater than or equal to 2; b is 0 or 1; p is preferably in the range of 2 to 5; and R is preferably a p-valent hydrocarbon group having 2 to 20 carbon atoms).

The component (B) is preferably a disilaalkane compound indicated by the below general formula.

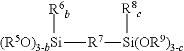

Within this formula, R⁵ and R⁹ are each an alkyl group or an alkoxyalkyl group; R⁶ (R⁸) is a monovalent hydrocarbon group; R⁷ is an optionally substituted alkylene having 2 to 19 carbon atoms; and b and c indicate 0 or 1.

Within this formula, R⁶ and R⁸ are each a monovalent hydrocarbon group as exemplified by alkyl groups such as the methyl group, ethyl group, propyl group, or the like; alkenyl groups such as the vinyl group, allyl group, or the like; and aryl groups such as the phenyl group or the like. Lower alkyl groups are preferred. R⁵ and R⁹ are each an alkyl group such as the methyl group, ethyl group, propyl group, or the like; or an alkoxyalkyl group such as the methoxyethyl group of the like; and the number of carbon atoms is preferably less than or equal to 4. R⁷ is an optionally substituted alkylene, and any linear or branched alkylene may be used without limitation. The alkylene may optionally be a mixture of alkylenes. From the standpoints of deep part curability, adhesivity, and reversion resistance, the alkylene is preferably a linear and/or branched alkylene having 2 to 20 carbon atoms; and the alkylene is particularly preferably a linear and/or branched alkylene having 5 to 10 carbon atoms. Hexylene, which has 6 carbon atoms, is particularly preferred. The non-substituted alkylene is a linear or branched form of the butylene group, pentylene group, hexylene group, heptylene group, octylene group, nonylene group, or decylene group. Such groups may have a hydrogen atom replaced by a methyl group, ethyl group, propyl group, butyl group, cyclopentyl group, cyclohexyl group, vinyl group, allyl group, 3,3,3-trifluoropropyl group, or 3-chloropropyl group.

Such components (B) are marketed as various types of compounds in the marketplace as reagents or products, or as may be required, may be synthesized using widely known methods such as the Grignard reaction, hydrosilylation reaction, or the like. For example synthesis is possible by the widely known hydrosilylation reaction method using a diene and a trialkoxysilane or organodialkoxysilane.

The component (B) is exemplified by bis(trimethoxysilyl)ethane, 1,2-bis(trimethoxysilyl)ethane, 1,2-bis(triethoxysilyl)ethane, 1,2-bis(methyldimethoxysilyl)ethane, 1,2-bis(methyldiethoxysilyl)ethane, 1,1-bis(trimethoxysilyl)ethane, 1,4-bis(trimethoxysilyl)butane, 1,4-bis(triethoxysilyl)butane, 1-methyldimethoxysilyl-4-trimethoxysilyl butane, 1-methyldiethoxysilyl-4-triethoxysilyl butane, 1,4-bis(methyldimethoxysilyl)butane, 1,4-bis(methyldiethoxysilyl)butane, 1,5-bis(trimethoxysilyl)pentane, 1,5-bis(triethoxysilyl)pentane, 1,4-bis(trimethoxysilyl)pentane, 1,4-bis(triethoxysilyl)pentane, 1-methyldimethoxysilyl-5-trimethoxysilyl pentane, 1-methyldiethoxysilyl-5-triethoxysilyl pentane, 1,5-bis(methyldimethoxysilyl)pentane, 1,5-bis(methyldiethoxysilyl)pentane, 1,6-bis(trimethoxysilyl)hexane, 1,6-bis(triethoxysilyl)hexane, 1,4-bis(trimethoxysilyl)hexane, 1,5-bis(trimethoxysilyl)hexane, 2,5-bis(trimethoxysilyl)hexane, 1-methyldimethoxysilyl-6-trimethoxysilyl hexane, 1-phenyldiethoxysilyl-6-triethoxysilyl hexane, 1,6-bis(methyldimethoxysilyl)hexane, 1,7-bis(trimethoxysilyl)heptane, 2,5-bis(trimethoxysilyl)heptane, 2,6-bis(trimethoxysilyl)heptane, 1,8-bis(trimethoxysilyl)octane, 2,5-bis(trimethoxysilyl)octane, 2,7-bis(trimethoxysilyl)octane, 1,9-bis(trimethoxysilyl)nonane, 2,7-bis(trimethoxysilyl)nonane, 1,10-bis(trimethoxysilyl)decane, and 3,8-bis(trimethoxysilyl)decane. A single type of bis(methoxysilyl)alkane may be used alone or a combination of two or more types may be used. From the standpoints of deep part curability, adhesivity, and reversion resistance, the component (B) of the present invention is preferably 1,6-bis(trimethoxysilyl)hexane, 1,6-bis(triethoxysilyl)hexane, 1,4-bis(trimethoxysilyl)hexane, 1,5-bis(trimethoxysilyl)hexane, 2,5-bis(trimethoxysilyl)hexane, 1-methyldimethoxysilyl-6-trimethoxysilyl hexane, 1-phenyldiethoxysilyl-6-triethoxysilyl hexane, or 1,6-bis(methyldimethoxysilyl)hexane.

The blended amount of component (B) relative to 100 parts by weight of the component (A) is 0.5 to 20.0 parts by weight. When R¹ in General Formula (1) indicating the component (A) is the hydrogen atom, the number of moles of the alkoxy group in the component (B) preferably exceeds the number of moles of silanol groups in the component (A), 0.75 to 10.0 parts by weight is particularly preferred. Within General Formula (1) showing the component (A), when R¹ is an alkyl group or alkoxyalkyl group, the blended amount of the component (B) relative to 100 parts by weight of the component (A) is preferably 2.0 to 10.0 parts by weight. On the other hand, when the blended amount of the component (B) is less than 0.5 parts by weight, the progress of curing is insufficient. An amount of the component (B) in excess of 20.0 parts by weight is problematic in that storage stability of the composition worsens, and the processing time required for molding the composition becomes extremely long.

The component (C) is water. By jointly using a fixed amount of water with the aforementioned component (B), deep part curability, adhesivity, and reversion resistance of the multi-component type curable silicone rubber composition of the present invention remarkably improves. The water may be added directly to one of the compositions of the multi-component type curable silicone rubber composition, or alternatively, the water may be added by separate preparation by addition of the water to a mixture or other raw materials.

The blended amount of the component (C) must be within a range that allows, by joint use with the component (B), realization of deep part curability and reversion resistance so as to Make possible use particularly in a terminal box or the like for solar cell use, and that does not inhibit curing. A compounded amount of the component (C) needs to be in a range of 0.05 to 2.0 parts by weight and is preferably in a range of 0.10 to 1.5 parts by weight per 100 parts by weight of the component (A). Moreover, due to the relationship with the utilized amount of the component (B), the blended amount of the aforementioned component (C) relative to the component (B) is preferably in the range (weight ratio) of 0.05 to 1.0, and particularly preferably is in the range of 0.10 to 0.5. When the utilized amount of the component (C) is less than the aforementioned lower limit, the technical effects of the present invention (i.e. deep part curability and reversion resistance) may not be realized. Exceeding the aforementioned upper limit of the utilized amount of the component (C) sometimes results in problems in that curing is inhibited or the obtained silicone rubber deteriorates over time.

The component (D) is a condensation curing catalyst. This component promotes the condensation reaction between the component (A) and component (B) and is used to cause the multi-component type curable silicone rubber composition of the present invention to cure and form silicone rubber. The curing catalyst is exemplified by an organic salt of a metal such as tin, titanium, zirconium, iron, antimony, bismuth, manganese, or the like; alcoholate and chelate compounds; amines such as hexylamine and dodecylamine; amine salts such as hexylamine acetate and decylamine phosphate; quaternary ammonium salts such as benzyl dimethyl ammonium acetate; and salts of alkali metals such as potassium acetate. Similarly, organic titanate esters and organic titanium chelate compound may be cited.

Specific examples of this type of condensation curing catalyst include: organic bismuth compounds such as bismuth octoate, bismuth neodecanoate, or the like; organic tin compounds such as dibutyl tin dilaurate, dibutyl tin dioctoate, dimethyl tin dineodecanoate, stannous octoate, or the like; and organic titanium compounds such as tetrabutyl titanate, tetrapropyl titanate, diisopropoxybis(acetylacetone) titanium, diisopropoxybis(ethylacetoacetate) titanium, or the like. Tin based compounds are particularly preferred for the present invention, and dialkyl type compounds are further particularly preferred as exemplified by dibutyl tin dilaurate and dimethyl tin dineodecanoate.

Additional example catalysts that may be used as the curing catalyst of the present invention without particular limitation are the bismuth compound type curing catalyst and/or titanium compound type curing catalysts disclosed, for example, in Japanese Unexamined Patent Application Publication No. 2009-132797, combinations of curing catalysts formed from such catalysts and iron compound type curing catalysts, the tin type curing catalysts disclosed in Japanese Unexamined Patent Application Publication No. 2009-191163, the condensation reaction promotion catalyst disclosed in Japanese Unexamined Patent Application Publication No. 2009-167420, or the like. Moreover, other condensation catalysts including aluminum, zirconium, zinc, or the like are preferably jointly used.

The added amount is a catalytic amount (i.e. effective amount), and this amount may be selected appropriately according to the desired curing rate and processing time interval. However, the amount of the curing catalyst relative to 100 parts per weight of the component (A) is generally 0.001 to 20 parts by weight, and an amount in the range of 0.01 to 5 parts by weight is preferred.

In addition to the aforementioned components (A) to (D), blending of an (E) inorganic power component in the composition of the present invention is preferred from the standpoints of further improving deep part curability of the composition of the present invention, causing an improvement of mechanical strength of the cured material of the composition of the present invention, and further improving pre-cure flow characteristics, flame retardancy of the cured composition, or the like. This component (E) is exemplified by: reinforcing silica powders such as dry-process silica powders, wet-process silica powders, or the like; quartz powder; diatomaceous earth; metal oxide powders such as aluminum oxide (alumina particulate), iron oxide, zinc oxide, titanium oxide, cerium oxide, or the like; metal hydroxide powders such as magnesium hydroxide, aluminum hydroxide, or the like; carbonate powders such as heavy (or dry type crushed) calcium carbonate, light (or precipitated) calcium carbonate, or the like; carbonate powders such as zinc carbonate or the like; talc, clay, mica, carbon black, glass beads, and such particles having undergone surface treatment by a hydrophobic agent such as trimethylchlorosilane, dimethyldichlorosilane, dimethyldimethoxysilane, hexamethyldisilazane, or octamethylcyclotetrasiloxane; as well as a calcium carbonate powder having undergone surface treatment with a fatty acid or a resin acid. Preferable examples among such powders are: reinforcing silica powders such as dry-process silica powders, wet-process silica powders, or the like; and quartz powder, cerium oxide powder, titanium oxide powder, carbon black, aluminum hydroxide powder, calcium carbonate powder, aluminum oxide powder, magnesium hydroxide powder, magnesium carbonate powder, and zinc carbonate powder. Among these examples, quartz powder and dry process silica are further preferred. In addition, those whose surface is treated using a hydrophobic agent such as described above can be used. This type of dry process silica is preferably used jointly with another aforementioned powder (such as quartz powder, cerium oxide powder, titanium oxide powder, or carbon black).

A compounded amount of the component (E) is in a range of 1 to 200 parts by weight and preferably in a range of 10 to 150 parts by weight per 100 parts by weight of the component (A). If the compounded amount of the component (E) is less than the lower limit of the range described above, the desired properties will tend not to improve and, if the compounded amount of the component (E) exceeds the upper limit of the range described above, the handling/workability of the composition of the present invention will tend to be impaired. Furthermore, when the component (E) is a fine powder such as reinforcing silica, light calcium carbonate, or carbon black, the blended amount is in the range of 5 to 60 parts by weight. When the particle size is relatively large (i.e. quartz powder or the like), the blended amount is preferably in the range of 10 to 200 parts by weight.

With the object of improving adhesion to each type of member, an adhesion-giving component (F) may be further blended in the composition of the present invention in a range so as not to impair the object and effect of the present invention. A known compound may be used as the component (F). Specific examples include non-component (B) alkoxysilanes such as amino group-containing alkoxysilanes such as 3-aminopropylmethyldimethoxysilane, 3-aminopropyltrimethoxysilane, 3-aminopropylmethyldiethoxysilane, 3-aminopropyltriethoxysilane, N-(β-aminoethyl)aminopropylmethyldimethoxysilane, N-(β-aminoethyl)aminopropyltrimethoxysilane, N-(β-aminoethyl)aminopropyltriethoxysilane, or the like; epoxy group containing alkoxysilanes such as 3-glycidoxypropyltrimethoxysilane or the like; mercapto group containing alkoxysilanes; and methacryl group-containing alkoxysilanes such as 3-acryloxypropyltrimethoxysilane or the like. The component (F) is also exemplified by alkoxy group containing carbasilatrane derivatives that are reaction mixtures of amino group containing alkoxysilanes and epoxy compounds. Such (F) adhesivity-giving agent components may be jointly used as two or more components.

The adhesion-giving component (F) is preferably the aforementioned amino group containing alkoxysilane or the alkoxy group containing carbasilatrane derivative that is a reaction mixture of the amino group containing alkoxysilanes and epoxy compounds. Furthermore, structure of a suitable alkoxy containing carbasilatrane derivative is disclosed in Japanese Unexamined Patent Application Publication No. 2009-132797 or the like. Joint use of the aforementioned component (B) and the reaction mixture of the amino group containing alkoxysilane and the epoxy compound has a combination of effects, i.e. increase of adhesivity of the cured material formed from the composition of the present invention, and the ability to improve water resistance of the cured material.

Although no particular limitation is placed on the blended amount of the adhesion-giving component (F), relative to 100 parts by weight of the component (A), this blended amount is preferably in the range of 0.1 to 20 parts by weight, and particularly preferably is in the range of 1.0 to 10 parts by weight.

A bifunctional silane and/or siloxane (G) may be added and blended in the composition of the present invention for further increasing elongation and lowering modulus. This type of bifunctional silane or siloxane is exemplified by dimethyl bis(N-methylacetoamidosilane), dimethyl bis(N-ethylacetoamido)silane, diphenyl bis(diethylaminoxy)silane, methylphenyl bis(diethylaminoxy)silane, 1,2,3,4-tetramethyl-1,2-diethyl-3,4-bis(N,N-diethylaminoxy)cyclotetrasiloxane, diphenyldimethoxysilane, dimethyldimethoxysilane, or the like. The siloxane is exemplified by non-reactive to weakly reactive silicone oils such as dimethylpolysiloxanes having both chain ends terminated by trimethylsiloxy groups and having a viscosity of 5 to 100,000 mPa·s, or the like. From the standpoints of high elongation and low modulus, a dimethylpolysiloxane having both chain ends terminated by trimethylsiloxy groups and having a viscosity of 5 to 100,000 mPa·s is preferably blended in the composition of the present invention.

The blended amount of this component relative to 100 parts by weight of the component (A) is in the range of 0.01 to 100 parts by weight, and the optimum blended amount is preferably selected according to the concentration of hydrolyzable groups in the component (A), the moisture content in the composition, or the like. When the aforementioned dimethylpolysiloxane having both chain ends terminated by trimethylsiloxy groups and having a viscosity of 5 to 100,000 mPa·s is blended, the preferred blended amount relative to 100 parts by weight of the component (A) is within the range of 1 to 100 parts by weight, and particularly preferably is in the range of 10 to 75 parts by weight.

In addition to the aforementioned components, as long as the object of the present invention is not impaired, various types of known additives may be added and blended in the room temperature-curing silicone rubber composition. Examples of additives include platinum compounds, zinc carbonate powders, and other flame retardants, plasticizers, thixotropy imparters, mildew-proofing agents, pigments, organic solvents, and the like.

Due to the composition of the present invention having multi-component type curing ability, by adopted this configuration, it is possible to contribute to uniform curing characteristics throughout (i.e. at both the surface layer and interior) without regard to moisture in the atmosphere, and it is possible to contribute to improvement of workability due to rapid curing. Specifically, the composition cures by combination of at least two components by blending the components (A) to (D), and as may be required, the component (E), component (F), and the aforementioned additives where there is no mutual reaction between additives. Specifically, a most preferred configuration includes: (I) a composition including the components (A) and (C) (and as may be required, the component (E), component (F), and the aforementioned additives), and (II) a composition including the components (B) and (D) (and as may be required, the component (E) and the aforementioned additives). However, as may be required, a three-component curing composition configuration may be adopted using a (I) composition of the components (A) and (B), (II) the component (C), and (III) the component (D).

Among such configurations, a room temperature curable silicone rubber composition is preferred that is formed from the (I) composition including at least the aforementioned component (A) and component (C) and not including the component (D), and the (II) component including at least the aforementioned component (D) and not including the components (A) and (C). Production is simple. The multi-component type room temperature curable silicone rubber composition provided with various types of characteristics (i.e. various curing rates, adhesivity values, or the like according to application or construction method) may be readily prepared by combination of one type of composition (I) and the composition- or blend ratio-modified composition (II).

In order to fill the terminal box, viscosity of the composition (I) is about 2,000 to 5,000 mP·s. Viscosity of the composition (II) may be adjusted to any value so as to make possible blending with the composition (I).

Prior to use, the plurality of separately stored compositions of the multi-component curable silicone rubber composition of the present invention are mixed. Examples of the mixing method include feeding the various components of the multi-component room-temperature-curable silicone rubber composition from their respective storage containers into a static mixer by means of a dosing pump, and mixing the components. When mixing the components of the multi-component room-temperature-curable silicone rubber composition in an open-type mixer prior to use, the composition is preferably defoamed prior to use.

The room temperature curable silicone rubber composition formed by blending of the separately stored multi-component type curable silicone rubber compositions of the present invention is readily attached to various types substrates or objects to be attached. Examples of objects to be attached and substrates are made from glass, ceramics, mortar, concrete, wood, aluminum, copper, brass, zinc, silver, stainless steel, iron, galvanized iron, tin, nickel-plated surfaces, epoxy resin, phenol resin or the like. Thermoplastic resins (such as polycarbonate resins, polyester resins, ABS resins, nylon resins, vinyl chloride resins, polyphenylene sulfide resins, polyphenylene ether resins, polybutylene terephthalate resins, or the like) may be blended in the composition, and if further strong adhesion is required, the aforementioned adhesion-giving component may be blended, and it is also permissible for a suitable primer to be coated on the surface of this object to be attached or substrate, and for the room temperature curable silicone rubber composition, formed by mixing of the separately stored multi-component type curable silicone rubber compositions of the present invention, to the attached to this primer coated surface.

Even when the curable silicone rubber composition produced by blending of the separately stored multiple compositions of the multi-component type curable silicone rubber composition of the present invention is thickly coated as potting material or is injected into a box and cured, deep part curability is excellent, good adhesion is expressed for various types of substrates (e.g. glasses, thermosetting resins, thermoplastic resins, metals, or the like), the cured surface is not sticky, and a silicone rubber is obtained that has strong adhesion to the substrate and has excellent post-curing reversion resistance. Due to the multi-component type curable silicone rubber composition of the present invention having such characteristics, the multi-component type curable silicone rubber composition of the present invention is suitable as a building material or a sealing agent, potting material, seal material, or adhesive for electric-electronic parts or automotive parts where there is concern for thermal loading. Specifically, use is possible with advantage as a sealing agent for glass bonding; a seal material for a bathtub unit; an adhesive or seal material for the illuminating parts of a vehicle such as an automobile or the like; and a seal material, coating agent, potting material, adhesive or the like for electric-electronic parts.

The multi-component type curable silicone rubber composition of the present invention has excellent deep part curability, adhesivity, and reversion resistance and is capable of imparting improved workability due to rapid curing, which is a characteristic of a multi-component type composition. Thus among such applications, the multi-component type curable silicone rubber composition of the present invention may be used appropriately as a material for electronic parts (such as a solar cell or the like) and especially as a potting material for a solar cell part. More specifically, the multi-component type curable silicone rubber composition of the present invention has the characteristics required for a potting material of a terminal box used for solar cells, i.e. a part required for the production of a solar cell module having excellent long-term durability and reliability.

The solar cell module of the present invention will be explained next in detail. The solar cell module of the present invention is characterized in that at least part of the members composing the module have cured material including the multi-component type curable silicone rubber composition of the present invention. A solar cell module generally is constructed by sealing the electricity generating part between glass and/or plastic, and attaching a terminal box to extended parts of electrodes. A curable resin composition is mainly used in this solar module for: (I) a seal material for sealing the module edge part; (II) an adhesive for the protective frame, reinforcing member, members used for installation, or the like; and (III) an adhesive for attachment of the terminal box; (IV) a sealing agent of the terminal box interior part, and the like. The solar cell module of the present invention is preferably the aforementioned multi-component type curable silicone rubber composition for at least one among these members (I) to (IV). The solar cell module preferably has a cured material (i.e. silicone rubber) formed from the multi-component type curable silicone rubber of the present invention as (IV) the sealing agent of the interior of the terminal box.

Since the terminal box for the solar cell panel composing the solar cell module is used in an exterior environment contacted by the wind and rain, there is danger that rain water may enter the interior of the terminal box and cause a current leak. In particular, the terminal box used for the solar cell panel uses a cable for external connection to extract and output current from the solar cell panel to the exterior by passing through openings arranged in the side wall or the like of the terminal box and is arranged so as to extend from the interior of the terminal box to the exterior. Thus rain water or the like readily invades the interior of the terminal box from the extended part of the cable. However, by loading the multi-component type curable silicone rubber composition of the present invention in the interior of the terminal box, this adverse effect is definitely prevented, and it is possible to provide a solar cell module that has excellent long-term durability and reliability.

The method of production of the terminal box of the present invention will be explained. No particular limitation is placed on the method of manufacture of the terminal box of the present invention, as long as the multi-component type curable silicone rubber composition of the present invention is used for filling or sealing part or the entire interior of the terminal box. However, the method of production of the terminal box of the present invention preferably includes a process for loading the multi-component type curable silicone rubber composition of the present invention into the interior of the terminal box and causing the multi-component type curable silicone rubber composition to cure.

Generally the production of a terminal box used for a solar cell module includes (i) electrically connecting the tips of cables for external connection to a terminal board, (ii) passing the cables through holes in the sidewall part of the terminal box housing and arranging the cables so that they extend from the interior to the exterior of the terminal box, and then (iii) fixing the terminals to the terminal box housing. At the installation site of the solar cell module, the terminals are electrically connected to the output lead wires from the solar cell panel in the completed terminal box, and the terminal box is attached to a certain position on the backside face of the solar cell panel using adhesive, double-sided tape, or the like. Finally, the multi-component type curable silicone rubber composition of the present invention is used to fill the interior of the terminal box. The filling multi-component type curable silicone rubber composition of the present invention is allowed to cure completely at room temperature. Thereafter, the solar cell module with the attached terminal box is placed at the installation location, i.e. the roof of a home or the like.

At this time, due to the use of the multi-component type curable silicone rubber composition of the present invention, it is possible to contribute to improvement of workability in the placement of the solar cell module due to rapid curing. In addition, the silicon rubber cured material filling the interior of the terminal box and having excellent deep part curability and adhesion completely shields the surface of the external connection cables and the interior of the terminal box, and it is possible to reliably prevent current leakage from the cables in the terminal box caused by rain water or the like. Furthermore, the multi-component type curable silicone rubber composition of the present invention has excellent reversion resistance. Then even when the multi-component type curable silicone rubber composition of the present invention is used for a long time outdoors, the problems of current leakage and water invading the interior of the terminal box over time are prevented, and it is possible to realize a solar cell module that has excellent long term durability and reliability.

### EXAMPLES

Hereinafter, examples will be used to describe the present invention in more detail. In the examples, the content of the components referred to as “parts” means “parts by weight.” The present invention is not limited by these examples. The value of viscosity (dynamic viscosity) is measured at 25° C.

### Examples 1 to 4, Comparative Examples 1 to 4

### Silicone Rubber Main Agent (I)

40 parts of (A1) dimethylpolysiloxane having a viscosity of 3,000 mPa·s and having both terminals of the molecular chain capped by silanol groups, 20 parts by weight of (G1) dimethylpolysiloxane having a viscosity of 100 mPa·s and having both terminals of the molecular chain capped by methyl groups, and 40 parts by weight of (E1) quartz powder were mixed until uniform. Then 0.2 parts of (C) water was further added and mixed to obtain a two-component type silicone rubber main agent used for examples.

A composition without the addition of water was prepared as the two-component type silicone rubber main agent used for comparative examples.

### Examples 1 to 4

### Curing Agent Mixture (II)

For the various examples shown in Table 1, the number of parts of (B1) 1,6-bis(trimethoxysilyl)hexane, (F1) aminoethylaminopropyl, and (D1) dimethyl tin dineodecanoate were blended as shown in Table 1 to produce the curing agent mixtures used for the examples.

### Comparative Examples 1 to 4

### Curing Agent Mixture (II)

For the various comparative examples, the number of parts shown in Table 1 of the added tetraisopropoxysilane, tetraethoxysilane, and (B1) 1,6-bis(trimethoxysilyl)hexane, (F1) aminoethylaminopropyl, and (D1) dimethyl tin dineodecanoate were blended to produce the curing agent mixtures used for the comparative examples.

### Examples 1 to 4, Comparative Examples 1 to 4

### Curability Testing of the Multi-Component Type Curable Silicone Rubber Composition

The aforementioned silicone rubber main agent (I) and curing agent mixture (II) were mixed uniformly, and the mixture was loaded into a plastic container having 20 cc volume and 2 cm depth. After the silicone rubber composition was left in this container for 24 h under 25° C. and 50 percent humidity conditions, the deep part curability and reversion resistance of the silicone rubber composition were evaluated by the below listed methods and criteria. The results are shown in Table 1.

[Deep Part Curability]

The cured material was removed from the container, and condition of the back face was observed and determined. Deep part curability was determined to be good for samples where curing reached the back face and there was no tackiness at the back face. Deep part curability was determined to have been poor when tackiness was confirmed on the back face or the back face was uncured so that the sample could not be removed from the container.

[Reversion Resistance]

A lid was used to close the container of the cured material prepared under the same conditions as described above without removal of the sample from the container. The assembly was heated for 1 week under 85° C. and 85 percent humidity conditions. Then the assembly was cooled down to room temperature, and the lid was removed. Hardness of the surface was measured by a hardness gauge based on JIS K6253. Samples having a measured hardness of zero were determined to be poor. Other samples were determined to be good.

TABLE 1

| | Examples | | | | Comparative Examples | | | |
|---|---|---|---|---|---|---|---|---|
| | 1 | 2 | 3 | 4 | 1 | 2 | 3 | 4 |
| Silicone rubber main agent (I), | containing water (0.2 parts) | | | | free of water | | containing water | |
| 100 parts | | | | | | | (0.2 parts) | |
| curing agent mixture (II) | | | | | | | | |
| tetraisopropoxysilane | | | | | | 1.0 | 1.0 | |
| partial hydrolysate of | | | | | | | | 1.0 |
| tetraethoxysilane | | | | | | | | |
| 1,6-bis(trimethoxysilyl)hexane | 2.0 | 1.0 | 1.0 | 0.5 | 1.0 | | | |
| aminoethylaminopropyl | | 1.0 | 2.0 | 2.0 | 1.0 | 1.0 | 1.0 | 1.0 |
| trimethoxysilane | | | | | | | | |
| dimethyl tin dineodecanoate | 0.05 | 0.05 | 0.05 | 0.05 | 0.05 | 0.05 | 0.05 | 0.05 |
| Evaluation results | | | | | | | | |
| deep curability | Good | Good | Good | Good | Poor | Poor | Good | Good |
| reversion resistance | Good | Good | Good | Somewhat | Good | Poor | Poor | Poor |
| | | | | poor | | | | |

[Example: Trial Production of Solar Cell Panel]

The curable silicone composition indicated previously in Example 3 was used as a sealing agent for a terminal box, and a test solar cell panel was produced. Even after 1000 h of accelerated aging at 85° C. and 85 percent humidity, the test-produced solar cell panel in immersed leak current testing displayed good insulation, i.e. less current leakage than the standard determined by the IEC (International Electrotechnical Commission) No. 61215.

1. A multi-component type curable silicone rubber composition comprising:
(A) 100 parts by weight of an organopolysiloxane capped at molecular terminals with an alkoxy group or a silanol group;
(B) 0.5 to 20.0 parts by weight of an organic compound having at least two alkoxysilyl groups within a single molecule and including a non-silicon-oxygen bond between the alkoxysilyl groups;
(C) 0.5 to 2.0 parts by weight of water; and
(D) a catalytic amount of a condensation curing catalyst;
wherein the multi-component type curable silicone rubber composition comprises multiple separately stored compositions.

2. The multi-component type curable silicone rubber composition according to claim 1, wherein said component (B) is a disilaalkane compound indicated by the following general formula: 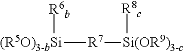
R⁵ and R⁹ are each an alkyl group or an alkoxyalkyl group; R⁶ and R⁸ are a monovalent hydrocarbon group; R⁷ is an optionally substituted alkylene group having 2 to 20 carbon atoms; and b and c are each 0 or 1.

3. The multi-component type curable silicone rubber composition according to claim 1, wherein a blended amount weight ratio of said component (C) relative to said component (B) is in a range of 0.05 to 1.0.

4. The multi-component type curable silicone rubber composition according to claim 1, further comprising:
(F) 0.1 to 20.0 parts by weight of an adhesion-giving component.

5. The multi-component type curable silicone rubber composition according to claim 1, wherein the multi-component type curable silicone rubber composition is a two-component type room temperature curable silicone rubber composition having:
(I) a composition including at least said component (A) and component (C), and not including said component (D); and
(II) a composition including at least said component (D), and not including said component (A) and component (C).

6. A material comprising the multi-component type curable silicone rubber composition according to claim 1, wherein the material is:
i) a potting material for electrical/electronic parts;
ii) a sealing agent for electrical/electronic parts; or
iii) an adhesive material for electrical/electronic parts.

7. A potting material for a solar cell component, the potting material comprising the multi-component type curable silicone rubber composition according to claim 1.

8. A solar cell module having a cured material comprising the multi-component type curable silicone rubber according to claim 1 as at least part of an article forming the module.

9. A solar cell module having, as at least part of a terminal box, a cured material that is the multi-component type curable silicone rubber composition according to claim 1.

10. A production method of a terminal box for a solar cell, wherein the method comprises a step of using the multi-component type curable silicone rubber composition according to claim 1.

11. The multi-component type curable silicone rubber composition according to claim 2, wherein a blended amount weight ratio of said component (C) relative to said component (B) is in a range of 0.05 to 1.0.

12. The multi-component type curable silicone rubber composition according to claim 2, further comprising:
(F) 0.1 to 20.0 parts by weight of an adhesion-giving component.

13. The production method according to claim 10, wherein the step of using is further defined as filling or sealing at least part of the terminal box with the multi-component type curable silicone rubber composition according to claim 1.

14. The multi-component type curable silicone rubber composition according to claim 1, wherein said component (A) comprises:
(A-1) a diorganopolysiloxane expressed by the following general formula; 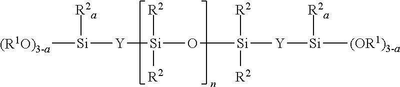
wherein R¹ represents a hydrogen atom, an alkyl group having from 1 to 10 carbons, or an alkoxyalkyl group; R² represents a group selected from a monovalent hydrocarbon group, a halogenated hydrocarbon group, and a cyanoalkyl group; Y represents an oxygen atom, a divalent hydrocarbon group, or a group expressed by the following general formula; 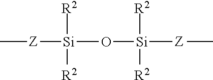
wherein Z is a divalent hydrocarbon group; a is 0, 1, or 2; and n is a number such that viscosity for said component (A-1) at 25° C. is 20 to 1,000,000 mPa·s.

15. The multi-component type curable silicone rubber composition according to claim 14, wherein said component (A) further comprises:
(A-2) a diorganopolysiloxane expressed by the following general formula; 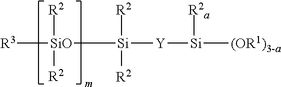
wherein R¹, R², Y, and a are as above; R³ represents an alkyl group having from 1 to 10 carbons or an alkenyl group; and m is a number such that viscosity for said component (A-2) at 25° C. is 20 to 1,000,000 mPa·s.

16. The multi-component type curable silicone rubber composition according to claim 15, wherein a weight ratio of (A-1):(A-2) is in the range of 100:0 to 20:80.
